(19) United States
(12) Patent Application Publication
(10) Pub. No.: US 2005/0287788 A1
(43) Pub. Date: Dec. 29, 2005

(54) Manufacturing method of nanowire array

(75) Inventors: Jeng-Hua Wei, Hsinchu (TW); Hung-Hsiang Wang, Hsinchu (TW); Po-Yuan Lo, Hsinchu (TW); Ming-Jer Kao, Hsinchu (TW)

Correspondence Address: Eric D. Cohen;Welsh & Katz, Ltd., 22nd Floor, 120 South Riverside Plaza, Chicago, IL, 60606, US

(73) Assignee: Industrial Technology Research Institute, Hsinchu (TW)

(21) Appl. No.: 10/914,273

(22) Filed: Aug. 9, 2004

(30) Foreign Application Priority Data
Jun. 25, 2004 (TW) 93118506

(51) Int. Cl. H01L 21/44; H01L 21/4763; H01L 21/31; H01L 21/469

(52) U.S. Cl. 438/618; 438/780

(57) ABSTRACT

This specification discloses a manufacturing method of nanowire array. The method includes the steps of: providing a substrate; forming an insulating layer on the substrate; forming a metal catalyst layer on the insulating layer by spin on glass (SOG), the metal catalyst being Au, Ag, or Pt; forming a covering layer on the metal catalyst layer by SOG; patternizing the covering layer exposed out of the metal catalyst layer; etching the exposed metal catalyst layer to form a patternized metal catalyst layer; and forming a plurality of nanowires in the patternized metal catalyst layer.

### BACKGROUND OF THE INVENTION

1. Field of Invention

The invention relates to a manufacturing method of nanowires and, in particular, to a manufacturing method of nanowire array.

2. Related Art

In the trend of miniaturizing integrated circuits (IC), the manufacturing processes based on silicon wafers have faced the technical bottleneck in optics and physics and pressure from R&D investments. People have been trying to make various kinds of nano-transistors so that hundreds of times more transistors can be accommodated in the same area of chip than the prior art.

Nanometer is a length unit, equal to one-billionth meter. In the research and development of various kinds of nano-transistors, structures involving nanowires as the basic elements have the most rapid progress. They are expected to be one of the best materials for nano-scale computer products. Therefore, how to make effective arrangements of the nanowires on a substrate or wafer is an important problem for researchers.

C. M Lieber et. al. shows a method of controlling the arrangement of nanowires in Science, 26 Jan., 2001, Vol. 291. One method involves the step of forming a poly-dimethylsiloxane (PDMS) mold on a substrate. A channel is then formed between the mold and the substrate. Afterwards, a suspension solution with nanowires flows through the channel structure, thereby depositing parallel nanowires thereon. Finally, the mold is removed.

Another method disclosed therein involves the steps of: forming a polymethylmethacrylate (PMMA) layer on a substrate; patternizing the PMMA layer; immersing the substrate in a solution with NH₂ ions so that the portion of the substrate without the PMMA contains NH₂ ions. After the nanowire solution flows by, nanowires will deposit at places with the NH₂ ions due to their attraction to the NH₂ ions.

The above-mentioned technology only describes how to use fluid to deposit existing nanowires in a single-layer array, and how to use the property that nanowires and NH₂ ions attract each other to form the desired array. Nevertheless, the method does not provide a good solution of controlling the formation orientation of the nanowires.

Therefore, it is not hard to see that there still exists a difficult problem in the method of forming nanowire array; that is, how to control the formation orientation of the nanowires in order to guarantee a highly-ordered nanowire array. We thus require a new manufacturing method to achieve the goal.

### SUMMARY OF THE INVENTION

In view of the foregoing, an objective of the invention is to provide a manufacturing method of nanowire array so that the formation orientation of the nanowires can be controlled while they are formed.

Another objective of the invention is to provide a manufacturing method of nanowire array in order to conveniently produce highly-ordered nanowire array.

A further objective of the invention is to provide a manufacturing method of nanowire array so that the nanowires are formed in parallel on the substrate or the wafer.

Yet another objective of the invention is to provide a manufacturing method of nanowire array that enables one to form nanowires at desired places using a patternized metal catalyst layer.

According to the above-mentioned objectives, a general embodiment of the invention includes the steps of: providing a substrate; forming an insulating layer on the substrate; forming a metal catalyst layer on the insulating layer by spin on glass (SOG); forming a covering layer on the metal catalyst layer by SOG; patternizing the covering layer exposed out of the metal catalyst layer; etching the exposed metal catalyst layer to form a patternized metal catalyst layer; and forming a plurality of nanowires in the patternized metal catalyst layer.

The step of forming a metal catalyst layer on the insulating layer by SOG includes the steps of: preparing a coating solution for the metal catalyst; covering the coating solution on the substrate by SOG; and drying the substrate.

The coating solution contains TEOS, a carbon-riched solution, and a metal catalyst. The metal catalyst is selected from the group consisting of Au, Ag, Pt, Ti, and their alloys. The carbon-riched solution is isoacetone.

The step of forming a covering layer on the metal catalyst layer by SOG includes the steps of: preparing a covering layer coating solution; covering the covering layer coating solution on the metal catalyst layer by SOG; and drying the substrate.

The covering layer coating solution contains TEOS.

The composition of the nanowire includes Si, GaP, and InP.

### BRIEF DESCRIPTION OF THE DRAWINGS

The invention will become more fully understood from the detailed description given hereinbelow illustration only, and thus are not limitative of the present invention, and wherein:

FIGS. 1A to 1F describe the disclosed manufacturing procedure of a nanowire array.

### DETAILED DESCRIPTION OF THE INVENTION

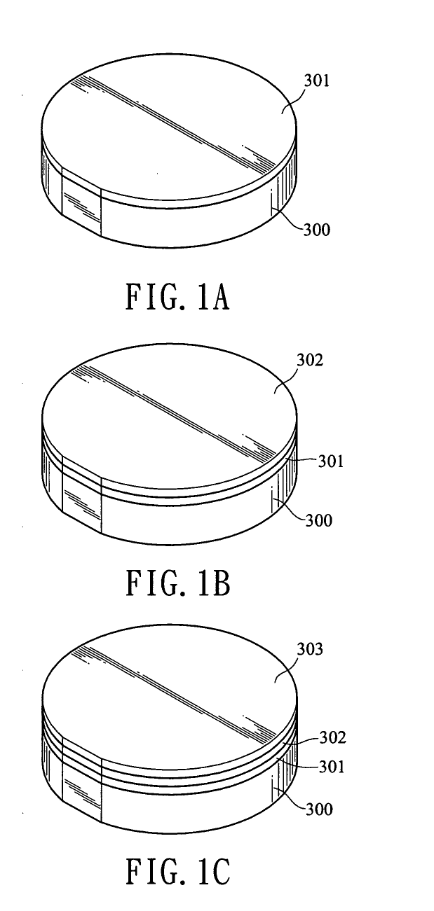

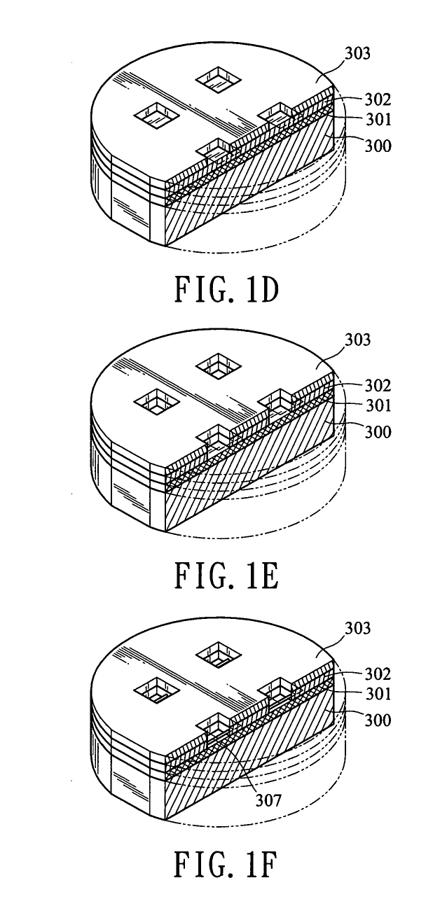

We use FIGS. 1A to 1F to describe an embodiment of the disclosed manufacturing process of nanowire array.

As shown in FIG. 1A, an insulating layer 301 is formed on a substrate 300. The insulating layer 301 contains SiO₂ or Si_{X}N_{Y}, formed by the chemical vapor deposition (CVD) method.

As shown in FIG. 1B, a metal catalyst layer 302 containing a metal catalyst is formed on the insulating layer 301. The formation method includes the steps of: preparing a coating solution for the metal catalyst; covering the coating solution on the insulating layer 301 by spin on glass (SOG); and drying the coating solution layer (not shown) on the insulating layer 301.

The coating solution contains TEOS, a carbon-riched solution, and a metal catalyst. The metal catalyst is selected from the group consisting of Au, Ag, Pt, Ti, and their alloys. The carbon-riched solution is isoacetone. The carbon-riched solution is isoacetone.

As shown in FIG. 1C, a covering layer 303 is formed on the metal catalyst layer 302. The covering layer does not contain the metal catalyst. Its formation method includes the steps of: preparing a covering layer coating solution; covering the covering layer coating solution on the metal catalyst layer 302 by SOG; and drying the covering layer coating solution on the metal catalyst layer 302.

The coating solution contains TEOS, a carbon-riched solution, and a metal catalyst.

As shown in FIG. 1D, after exposure and development the covering layer 303 is formed with a pattern by dry or wet etching. The patternized covering layer exposes part of the metal catalyst layer 302. Therefore, viewing from the front of the substrate, one can see a plurality of concave holes exposing the metal catalyst layer 302.

As shown in FIG. 1E, the metal catalyst layer 302 exposed from the patternized covering layer 303 can be removed by dry or wet etching. Therefore, viewing from the front of the substrate, one can see a plurality of concave holes exposing the insulating layer 301.

As shown in FIG. 1F, a nanowire 307 is formed in the patternized metal catalyst layer 302. Both ends of the nanowire 307 are connected between the metal catalyst layer 302. Its formation method includes the step of using the catalyst of the metal catalyst layer 302 as a catalyst for reactions under appropriate conditions.

The appropriate reaction conditions are different for different choices of metal catalyst ions. For example, if the metal catalyst ion is Au and the carbon-riched solution is isoacetone, the appropriate reaction conditions are that the reaction temperature is between 410° C. and 490° C., the pressure is between 1 torr and 20 torr, and the reaction time is between 10 min and 20 min.

Since the covering layer 303 does not contain the metal catalyst according to the above-mentioned method, the nanowires are only formed in the metal catalyst layer 302. Moreover, as the metal catalyst layer 302 is covered by the covering layer 303, the nanowires will not form on the surface of the metal catalyst layer 302. Therefore, using the disclosed method can readily form nanowire array on a wafer or substrate. The orientation of the nanowires can be controlled at the same time they are formed, rendering highly-ordered nanowires.

Certain variations would be apparent to those skilled in the art, which variations are considered within the spirit and scope of the claimed invention.

1. A manufacturing method of a nanowire array, comprising the steps of:
providing a substrate;
forming an insulating layer on the substrate;
forming a metal catalyst layer on the insulating layer by spin on glass (SOG);
forming a covering layer on the metal catalyst layer by SOG;
patternizing the covering layer exposed out of the metal catalyst layer;
etching the exposed metal catalyst layer to form a patternized metal catalyst layer; and
forming a plurality of nanowires in the patternized metal catalyst layer.

2. The manufacturing method of claim 1, wherein the insulating layer is made of a material selected from the group consisting of SiO₂ and SiₓN_{y}.

3. The manufacturing method of claim 1, wherein the insulating layer is formed by chemical vapor deposition (CVD).

4. The manufacturing method of claim 1, wherein the step of forming a metal catalyst layer on the insulating layer by SOG includes the steps of:
preparing a coating solution for the metal catalyst;
covering the coating solution on the substrate by SOG; and
drying the substrate.

5. The manufacturing method of claim 4, wherein the coating solution contains TEOS.

6. The manufacturing method of claim 4, wherein the coating solution contains a carbon-riched solution.

7. The manufacturing method of claim 6, wherein the carbon-riched solution is iso acetone.

8. The manufacturing method of claim 1, wherein the metal catalyst is selected from the group consisting of Au, Ag, Pt, and Ti.

9. The manufacturing method of claim 1, wherein the metal catalyst is selected from the group consisting of the alloys of Au, Ag, Pt, and Ti.

10. The manufacturing method of claim 1, wherein the metal catalyst is Au.

11. The manufacturing method of claim 1, wherein the step of forming a covering layer on the metal catalyst layer by SOG includes the steps of:
preparing a covering layer coating solution;
covering the covering layer coating solution on the metal catalyst layer by SOG; and
drying the substrate.

12. The manufacturing method of claim 1, wherein the covering layer coating solution contains TEOS.

13. The manufacturing method of claim 1, wherein the step of forming a plurality of nanowires in the patternized metal catalyst layer includes the step of using the metal catalyst in the metal catalyst layer as a catalyst to have reactions above 400° C. for the formation of the nanowires.

14. The manufacturing method of claim 1, wherein the substrate is a silicon wafer.

15. The manufacturing method of claim 1, wherein the nanowire is made of a material selected from the group consisting of Si, GaP, and InP.
